(19) United States
(12) Patent Application Publication
(10) Pub. No.: US 2025/0243108 A1
(43) Pub. Date: Jul. 31, 2025

(54) GLAZING HAVING A COMMUNICATION WINDOW FOR SENSORS AND CAMERA SYSTEMS

(71) Applicant: SAINT-GOBAIN GLASS FRANCE, COURBEVOIE (FR)

(72) Inventors: Jan HAGEN, HERZOGENRATH (DE); Simon LE MOAL, HERZOGENRATH (DE); Bernard NGHIEM, HERZOGENRATH (DE)

(21) Appl. No.: 18/855,975

(22) PCT Filed: Apr. 5, 2023
(86) PCT No.: PCT/EP2023/058966

§ 371 Date: Oct. 10, 2024

(30) Foreign Application Priority Data
Apr. 11, 2022 (EP) 22167616.6

(51) Int. Cl. C03C 17/22

(52) U.S. Cl. CPC C03C 17/22; C03C 2217/28; C03C 2218/1525

(57) ABSTRACT

A glazing includes a first pane with an exterior-side surface and an interior-side surface, wherein a coating made of diamond-like carbon (DLC) is arranged on the exterior-side surface with an atmospheric pressure chemical vapor deposition method.

The invention is in the field of glazings, in particular for sensors and camera systems, a glazing arrangement, a method for producing the glazing, and its use.

Motor vehicles, airplanes, helicopters, and ships are increasingly equipped with various sensors or camera systems. Examples include camera systems, such as video cameras, night vision cameras, residual light amplifiers, laser rangefinders, or passive infrared detectors. Vehicle identification systems are also increasingly used, for example, for toll collection.

Camera systems can utilize light in the ultraviolet (UV), visible (VIS), and infrared wavelength range (IR). With these, objects, vehicles, and persons can be accurately identified even under poor weather conditions, such as darkness and fog. In motor vehicles, these cameras can be placed behind the windshield in the passenger compartment, behind the rear window, but also behind side windows or other glazing elements. In road traffic, they also provide the possibility of recognizing dangerous situations and obstacles in a timely manner.

High-value sensors and sophisticated camera systems, as are necessary, for example, for modern traffic sign recognition or autonomous driving (so-called vision-based driver assistance systems, FAS, or advanced driver assistance systems, ADAS) require very high, undisturbed, and low-scatter through-vision in the region of their beam path through the pane.

Normal fogging and icing can have a significant adverse effect on this beam path. Suitable ventilation or heating systems as known, for example, from DE 10 2012 018 001 A1 provide a remedy.

In addition, micro-defects and scratches on the outer face (exterior-side surface) of the of the pane are particularly disturbing and disadvantageous for sophisticated optical systems. These develop, for example, from abrasion by impacting sand grains or wiper blades moving over them.

For many applications, it is therefore desirable to provide a pane surface having improved scratch resistance. For example, the soda lime glass customarily used for vehicle glazings does not inherently have high scratch resistance, in particular with exposure to sand grains in combination with moving wiper blades.

Here, for example, a full-surface coating of the exterior-side surface of the glazing with a layer of diamond-like carbon (DLC) provides a remedy, as disclosed in US2003190476A1. This layer can significantly improve the scratch resistance of the glass surface.

Diamond-like carbon (DLC) consists of a mixture of sp³- and sp²-hybridized carbon and is characterized by an amorphous structure. Thin layers of diamond-like carbon are, in principle, well suited for improving the scratch resistance of a surface, since they have a low coefficient of friction and sufficiently high hardness.

Method for producing DLC layers are widely known. For example, WO 2016/171627 A1 describes coating a substrate wherein the thin layer comprises a carbon layer such as DLC. The DLC layer is applied by physical vapor deposition, e.g., by high-power pulse magnetron sputtering. WO 2019/020481 A1 further describes a method for depositing DLC layers by a PECVD magnetron process.

By means of such processes, large flat glass areas can be provided with DLC layers in high quality. However, modern vehicle glazing usually has curvature and/or is thermally toughened. During their manufacture, coatings are usually applied full-surface to flat, planar panes, which are then trimmed and subsequently appropriately thermally treated, for example, during bending.

One problem with DLC layers is their temperature sensitivity. At high temperatures, the diamond-like carbon graphitizes (i.e., a shift occurs: from sp³ to sp² coordination of the carbon atoms) and burns to CO₂ at temperatures of >400° C. Since glass bending processes and glass hardening processes (annealing) require temperatures up to 700° C., pure DLC layers on glass burn and disappear if they are not protected against oxidation. To avoid oxidation, complex techniques using protective layers and release layers are necessary to prevent DLC layers from burning away during temperature treatment for bending or annealing. Such approaches are described in WO 2004/071981, U.S. Pat. No. 7,060,322 B2, U.S. Pat. No. 8,443,627, or U.S. Pat. No. 8,580,336 B2.

The washing processes described to date in the prior art for removal of annealing protective coatings for the protection of the DLC layer during a heat treatment are complex and have various disadvantages. For one thing, the removal of the protective layer in this way can proceed unreliably and incompletely, in particular due to curved pane geometries. The exposed substrate with the applied DLC layer must subsequently undergo a drying step. Moreover, the washing medium used is correspondingly contaminated with the components of the protective layers washed off and must be disposed of in a complex and costly manner that is environmentally compatible and complies with requirements.

WO 2021/043838 A1 and WO 2021/112144 A1 avoid bending the DLC layer on a glass by inserting a transparent element coated in advance with a DLC layer over its entire surface, preferably a polycrystalline element or a chalcogenite glass into a recess in a glass pane.

DE 10 2012 200969 A1 describes a carbon deposition process of coatings with anti-fingerprint properties using an atmospheric plasma open jet, in which flat operating elements of household appliances and in particular glass ceramic plates are coated over their entire surface. Here, it is possible, by varying the process parameters, to selectively change different amorphous carbon configurations from graphite-like to diamond-like structure.

WO 2018/054595 A1 describes a method for ablating and patterning functional coatings on curved surfaces using a laser.

The object of the present invention is now to provide an improved glazing with a scratch-resistant coating on the exterior-side surface that can be produced simply and economically.

The scratch-resistant coating protects in particular the through-vision region of optical sensors or camera systems through the glazing surface such that their optical properties are little impaired.

The object of the present invention is accomplished according to the invention by a glazing in accordance with claim 1. Preferred embodiments are apparent from the subclaims.

The glazing according to the invention is in particular a vehicle glazing and comprises at least the following features:
a first pane with an exterior-side surface and in interior-side surface, wherein
a coating made of diamond-like carbon (DLC) is arranged on the exterior-side surface of the first pane.

In the following, the coating made of diamond-like carbon (DLC) according to the invention is also referred to in short as the DLC coating or simply coating.

In an advantageous embodiment of a glazing according to the invention, the coating made of diamond-like carbon (DLC) has higher scratch resistance than the exterior-side surface of the first pane (i.e., the exterior-side surface without coating).

The first pane is advantageously monolithic, i.e., the first pane is advantageously formed from a continuous material. In particular, the first pane has no openings or recesses that are filled with a different material. As a result, the exterior-side surface of the first pane forms a continuous and uniform surface.

In an advantageous embodiment of a glazing according to the invention, the DLC coating is arranged on the exterior-side surface in some sections and preferably not over the entire surface.

In another advantageous embodiment of a glazing according to the invention, an area of the DLC coating is from 0.1% to 95%, preferably from 0.1% to 30%, particularly preferably from 0.5% to 10% of an area of the exterior-side surface of the first pane. Here, “area of the DLC coating” means the area of the exterior-side surface of the first pane provided with the DLC coating. Here, “area of the first pane” means the total area of the exterior-side surface of the first pane.

In another advantageous embodiment of a glazing according to the invention, the DLC coating consists of a closed region that does not include any uncoated zones.

The coating according to the invention contains or consists of a diamond-like carbon, with the “diamond-like carbon” abbreviated to DLC here and in the following, as is common. Coatings made of diamond-like carbon are generally known. In DLC layers, hydrogen-free or hydrogen-containing amorphous carbon is the predominant component, wherein the carbon can consist of a mixture of sp³- and sp²-hybridized carbon. Optionally, sp³-hybridized carbon or sp²-hybridized carbon can predominate. Examples of DLC include those referred to as ta-C and a: C—H. The DLC layer can be doped or undoped. Doping elements are, for example, silicon, metals, oxygen, nitrogen, or fluorine.

In an advantageous embodiment, the carbon of the DLC coating comprises or consists of a mixture of sp³- and sp²-hybridized carbon, preferably with a proportion of at least 20% sp³-hybridized, particularly preferably of at least 40% sp³-hybridized carbon.

DLC coatings have advantageous properties such as high scratch resistance and, at the same time, high transparency. The scratch resistance is measured, for example, using an Erichsen Hardness Tester or Erichsen Scratch Tester.

The DLC coating according to the invention is advantageously deposited on the exterior-side surface of the first pane using a process for atmospheric pressure chemical vapor deposition (AP-CVD) and in particular using a process for atmospheric pressure plasma-enhanced chemical vapor deposition (AP-PECVD).

Processes for the deposition of a layer in an atmospheric pressure plasma are sufficiently known, wherein the plasma is preferably generated by a discharge between electrodes and at least one organic coating precursor compound is fed into the region of the relaxing plasma and is deposited as a plasma polymeric layer on a substrate. Reference is made here, merely by way of example, to WO2018141802A1.

Advantageously, the at least one organic coating precursor compound is selected from the group consisting of non-cyclic or cyclic, non-functionalized or functionalized hydrocarbons.

In a preferred embodiment, the at least one organic coating precursor compound is selected from tetramethylsilane (TMS), alkanes with 1 to 10 carbon atoms, alkynes with 2 to 10 carbon atoms, benzene, or mixtures thereof. Examples of alkynes with 2 to 10 carbon atoms are ethyne, propyne, butyne, pentyne, hexyne, heptyne, octyne, nonyne, decyne, and isomers thereof. Examples of alkanes with 1 to 10 carbon atoms are methane, ethane, propane, butane, pentane, hexane, heptane, octane, nonane, decane, and isomers thereof. The at least one organic coating precursor compound is selected in particular from tetramethylsilane (TMS), methane (CH₄), ethyne (C₂H₂), or combinations thereof. It goes without saying that mixtures of the above-mentioned coating precursor compounds can also be used as the coating precursor compound.

In particular, the organic coating precursor compound consists of acetylene (C₂H₂).

Preferably, nitrogen, neon, argon, krypton, xenon, or forming gas is used as the inert or process gas.

In an advantageous embodiment of a glazing according to the invention, the coating made of diamond-like carbon has eine thickness d of 1 nm to 20 nm, preferably of 2 nm to 10 nm, particularly preferably of 3 nm to 10 nm. DLC coatings of such thicknesses have good scratch resistance properties along with high optical transparency.

The terms “interior-side surface” and “exterior-side surface” are used to distinguish the surface of the pane. In the installed position, the exterior-side surface preferably faces an exterior space, for example, in the case of a vehicle glazing, the exterior space around the vehicle; and the interior-side surface preferably faces an interior space, for example, in the case of a vehicle glazing, the interior of the vehicle.

In an advantageous embodiment of a glazing according to the invention, the DLC coating has sufficient transmittance T_{L}, both at an angle α of 0° and at angles α from −80° to +80°, to ensure unobstructed through-vision for sophisticated optical sensors and camera systems (particularly in terms of light sensitivity and dynamics).

In an advantageous embodiment, the glazing according to the invention has, in the region of the DLC coating, transmittance T_{L} in the visible spectral range at an angle α=0° of at least 70%. In particular, the glazing according to the invention has, in the region of the DLC coating, transmittance T_{L} in the visible spectral range at an angle α=0° of at least 75%. The term “visible spectral range” means the spectral range from 400 nm to 750 nm. The transmittance is preferably determined in accordance with the standard DIN EN 410.

In an advantageous embodiment of the glazing according to the invention, using the example of a composite pane, the interior-side surface of the first pane is joined flat to an exterior-side surface of the second pane via at least one thermoplastic intermediate layer, for example, by lamination.

The glazing according to the invention can have further thin layers, for example, IR-reflecting layers that protect a vehicle interior against solar radiation or thermal radiation reflecting layers that are also referred to as low emissivity layers, emissivity reducing layers, or low-E layers. Low-E layers have in particular the function of reflecting thermal radiation, i.e., in particular IR-radiation, which has longer wavelength than the IR component of solar radiation. With low outside temperatures, the low-E coating reflects heat back into the interior and reduces the cooling of the interior. At high outside temperatures, the low-E coating reflects the thermal radiation of the heated composite pane outward and reduces the heating of the interior. On the interior-side surface (inner face) of the second pane (inner pane), the coating according to the invention particularly effectively reduces the emission of thermal radiation from the pane into the interior in the summer and reduces the dissipation of heat into the external surroundings in the winter.

Furthermore, the glazing can have further functional elements such as electrically controllable optical functional elements, such as illumination elements (for example, OLEDs) or shading elements (for example, electrochromic functional elements or PDLC, SPD, or guest-host cell elements).

In principle, all electrically insulating substrates that are thermally and chemically stable as well as dimensionally stable under the conditions of production and use of the pane according to the invention are suitable as the first and, if applicable, the second pane.

The first pane preferably contains or consists of glass, particularly preferably flat glass, float glass, quartz glass, borosilicate glass, soda lime glass, or clear plastics, preferably rigid clear plastics, in particular polyethylene, polypropylene, polycarbonate, polymethyl methacrylate, polystyrene, polyamide, polyester, polyvinyl chloride, and/or mixtures thereof. The second pane, if present, preferably contains or consists of glass, particularly preferably flat glass, float glass, quartz glass, borosilicate glass, soda lime glass, or clear plastics, preferably rigid clear plastics, in particular polyethylene, polypropylene, polycarbonate, polymethyl methacrylate, polystyrene, polyamide, polyester, polyvinyl chloride, and/or mixtures thereof.

The first pane and/or the second pane are preferably transparent, in particular for use of the pane as a windshield or back window (rear window) of a vehicle or other uses where high light transmittance is desired.

The first pane and/or, if present, the second pane are advantageously monolithic, i.e., they have, in each case, no recesses or inserts, for example, of a different (transparent) material.

The thickness of the pane can vary widely and can thus be ideally adapted to the requirements of the individual case. Preferably used are panes with the standard thicknesses from 1.0 mm to 25 mm, preferably from 1.4 mm to 5.9 mm for vehicle glass, and preferably from 4 mm to 25 mm for furniture, appliances and buildings, in particular electric radiators. The size of the pane can vary widely and is governed by the size of the use according to the invention. The first pane and, optionally, the second pane have, for example, in the vehicle construction and architectural sector, customary areas of 200 cm² up to 20 m².

The pane can have any three-dimensional shape desired. Preferably, the three-dimensional shape has no shadow zones such that it can be coated, for example, by cathodic sputtering with IR layers or low-E layers. Preferably, the substrates are planar or slightly or highly curved in one or more spatial directions. In particular, planar substrates are used. The panel can be colorless or colored.

A plurality of panes are joined to one another by at least one intermediate layer. The intermediate layer preferably contains at least one thermoplastic, preferably polyvinyl butyral (PVB), ethylene vinyl acetate (EVA), and/or polyethylene terephthalate (PET). However, the thermoplastic intermediate layer can also contain, for example, polyurethane (PU), polypropylene (PP), polyacrylate, polyethylene (PE), polycarbonate (PC), polymethyl methacrylate, polyvinyl chloride, polyacetate resin, casting resins, acrylates, fluorinated ethylene propylenes, polyvinyl fluoride, and/or ethylene tetrafluoroethylene, or copolymers or mixtures thereof. The thermoplastic intermediate layer can be formed by one or even by multiple thermoplastic films arranged one over another, with the thickness of a thermoplastic film preferably being from 0.25 mm to 1 mm, typically 0.38 mm or 0.76 mm.

Another aspect of the invention comprises a glazing arrangement, comprising:
a glazing according to the invention and
at least one optical sensor or at least one camera system, whose beam path is directed at least in some sections and preferably completely onto or through the region of the DLC coating.

The region of the DLC coating enables particularly good and undisturbed communication of the optical sensor or the camera system through the glazing and is commonly also referred to as a communication window. The passage region of the beam path through the glazing and in particular through the exterior-side surface of the first pane is commonly referred to as a camera window or a camera zone.

In an advantageous embodiment of a glazing arrangement according to the invention, the region of the DLC coating (i.e., the communication window) completely contains the passage region of the beam path through the first pane (i.e., the camera window). Particularly preferably, the passage region of the beam path (camera window) is essentially congruent with the region of the DLC coating (communication window).

In an advantageous embodiment of the glazing according to the invention arrangement, an angle α (alpha) between the surface normal on the interior-side surface of the first pane and the center of the beam path of the optical sensor or camera system is from 0° to 80°, preferably from 10° to 75°, and particularly preferably from 30° to 75°. Preferably, the center of the beam path is substantially horizontal. Low values from 10° to 30° are often used in commercial vehicles, in particular agricultural utility vehicles such as tractors, trucks, or buses. Values between 30° and 75° are frequently used in passenger cars, with values between 50° and 75° preferred in sports cars. The angles mentioned are understood as angles between the surface normal of the glazing and the center of the beam path. If the center of the beam path is horizontal, the angles α correspond to the inclination of the glazing in the installed position relative to the vertical.

The camera system according to the invention is preferably a high-performance camera system (in particular in terms of dynamics and range), in particular for vision-based driver assistance systems (FAS) or advanced driver assistance systems (ADAS).

The invention further includes a method for producing a glazing according to the invention, at least comprising the following steps in the order indicated:
a) Annealing or bending at least a first pane at a temperature of more than 400° C., preferably of more than 500° C., and
b) Depositing a coating made of diamond-like carbon (DLC) on the exterior-side surface of the first pane with an atmospheric pressure chemical vapor deposition method (AP-CVD), preferably with an atmospheric pressure plasma-enhanced chemical vapor deposition method (AP-PECVD).

The temperature treatment in step a) can be carried out in various ways, for example, by heating the pane using a furnace or radiant heater. Alternatively, the temperature treatment can also be carried out by irradiation with light, for example, using a lamp or a laser as a light source.

The first pane can be bent in step a), typically at a temperature of 500° C. to 700° C.

In an advantageous embodiment, the temperature treatment is done as a thermal prestressing process. In this case, the heated substrate is subjected to an air flow, rapidly cooling it. Compressive stresses develop at the pane surface; tensile stresses, in the core of the pane. The characteristic stress distribution increases the breaking strength of the glass panes. A bending process can also precede the prestressing.

In an advantageous further development of the method according to the invention, prior to step b), an adhesion layer is deposited on the first pane, preferably with an atmospheric pressure chemical vapor deposition method (AP-CVD), and particularly preferably with an atmospheric pressure plasma-enhanced chemical vapor deposition method (AP-PECVD). The adhesion layer is preferably silicon oxide-based or is made of silicon oxide. The DLC coating is subsequently deposited on the adhesion layer, in particular substantially congruently.

In an advantageous further development of the method according to the invention, the DLC coating is deposited from a plasma nozzle on a subregion of the exterior-side surface of the first pane (i.e., only locally). If present, the adhesion layer can also be deposited from a plasma nozzle on a subregion of the exterior-side surface of the first pane (i.e., only locally).

Since the deposition of the DLC coating is done only locally, the plasma nozzle is preferably moved in tracks over immediately adjacent regions of the exterior-side surface of the first pane, and the DLC coating is deposited.

In an advantageous further development of the method according to the invention, all steps following step b) for producing the glazing according to the invention are carried out at temperature lower than 400° C., preferably lower than 300° C., particularly preferably lower than 200° C. In other words, the glazing according to the invention with the DLC coating is no longer heated to or above 400° C., preferably no longer to or above 300° C., and particularly preferably no longer to or above 200° C. This has the effect that the DLC coating does not burn away or become damaged by the effect of temperature.

In an intermediate step between steps a) and b) or in a further step c), a composite pane can be produced by bonding (lamination) of the first pane, a thermoplastic intermediate layer, and a second pane.

The bonding of the first and the second pane is preferably carried out under the action of heat, vacuum, and/or pressure. Methods known per se for producing a pane can be used.

For example, so-called autoclave methods can be carried out at an elevated pressure of approx. 10 bar to 15 bar and temperatures from 130° C. to 145° C. for approx. 2 hours. Vacuum bag or vacuum ring methods known per se operate, for example, at approx. 200 mbar and 80° C. to 110° C. The first pane, the thermoplastic intermediate layer, and the second pane can also be pressed between at least one roller pair in a calendar to form a pane. Facilities of this type are known for the production of panes and normally have at least one heating tunnel upstream from a press. The temperature during the pressing operation is, for example, from 40° C. to 150° C. Combinations of calendar and autoclave methods have proved particularly useful in practice. Alternatively, vacuum laminators can be used. These consist of one or more heatable and evacuable chambers in which the first pane and the second pane are laminated, for example, within approx. 60 minutes at reduced pressures of 0.01 mbar to 800 mbar and temperatures from 80° C. to 170° C.

It goes without saying that lamination after application of the coating made of diamond-like carbon in step b) can be carried out only under temperatures and process conditions that do not damage the coating.

The invention further includes the use of the glazing according to the invention or of the glazing arrangement according to the invention in buildings, in particular in the access area, window area, roof area, or façade area, as a built-in part in furniture and appliances, in means of locomotion for travel on land, in the air, or on water, in particular in trains, ships, and motor vehicles, for example, as a windshield, rear window, side window, and/or roof panel. The use includes optical sensors and camera systems, in particular for vision-based driver assistance systems, FAS, or advanced driver assistance systems, ADAS, whose beam path passes through the coated communication window.

In the following, the invention is explained in greater detail with reference to drawings and exemplary embodiments. The drawings are a schematic representation and are not to scale. The drawings in no way restrict the invention.

They depict:

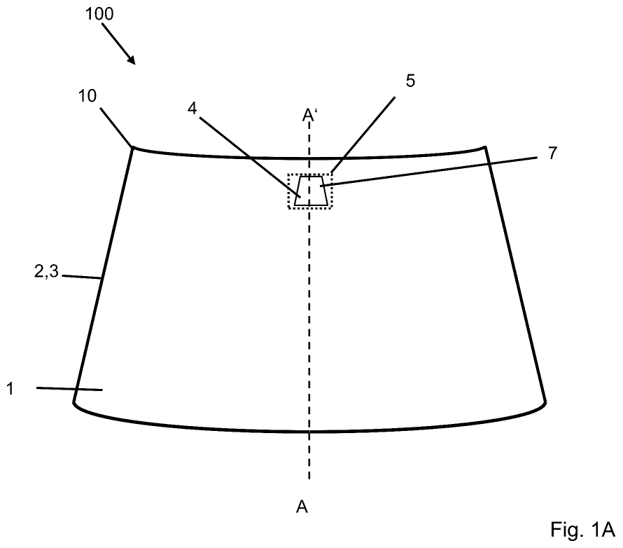

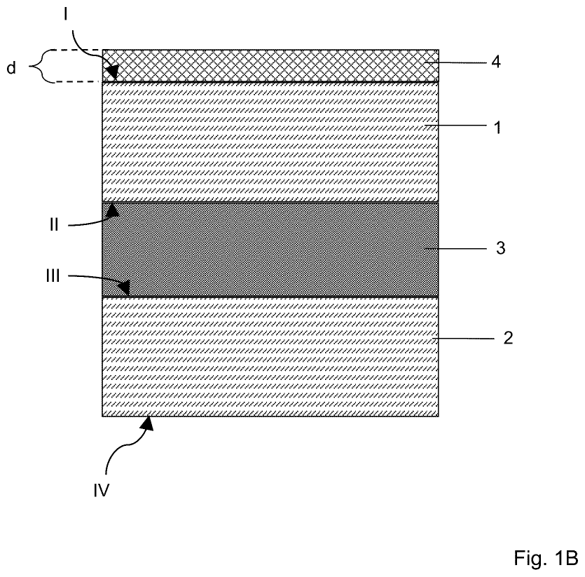

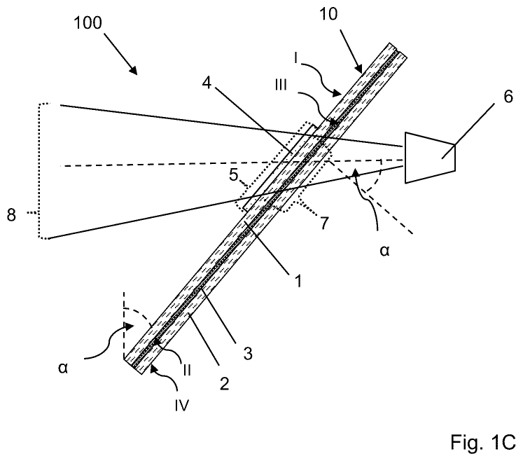

FIG. 1A a plan view of an embodiment of a glazing according to the invention,

FIG. 1B a schematic cross-sectional representation of the layer structure of the glazing of FIG. 1A,

FIG. 1C a schematic representation of a glazing arrangement according to the invention with a cross-sectional representation along the section line A-A′ through the glazing of FIG. 1A,

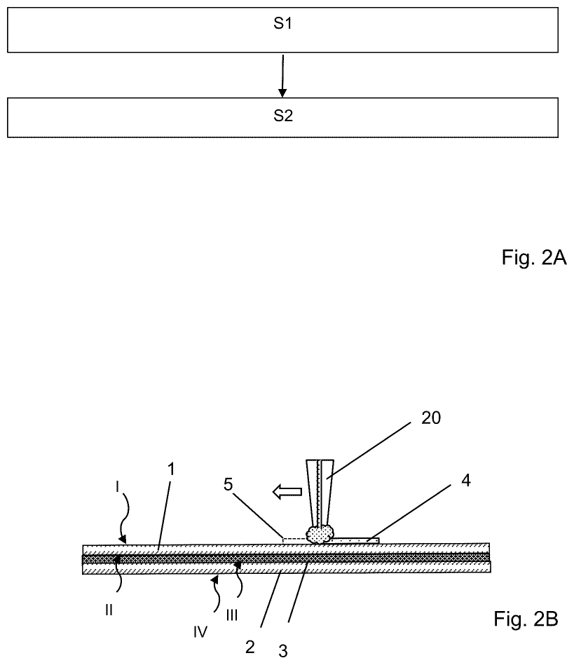

FIG. 2A a flow chart of an embodiment of the method according to the invention,

FIG. 2B a detailed view during the step S2 during production of a glazing 10 according to the invention in accordance with the example according to the invention of FIG. 1A-C, and

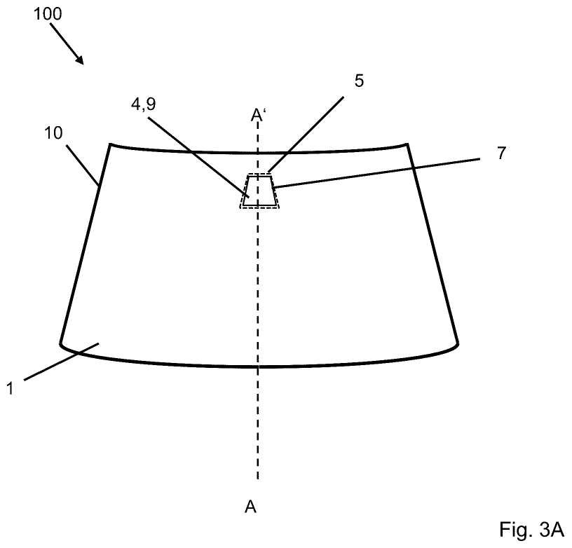

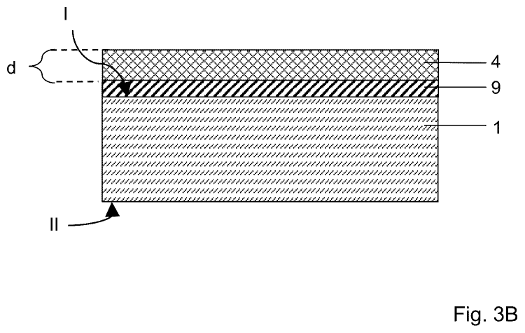

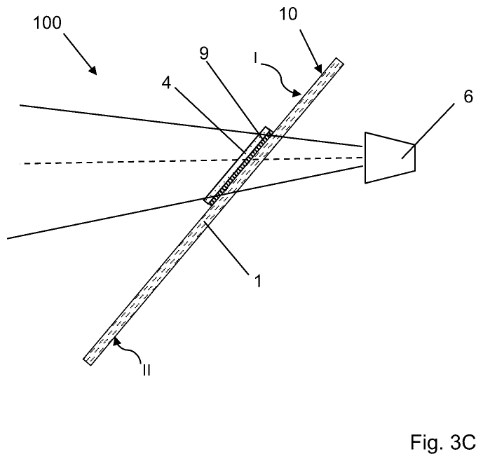

FIG. 3A a plan view of another embodiment of the glazing according to the invention,

FIG. 3B a schematic cross-sectional representation of the layer structure of the glazing of FIG. 3A,

FIG. 3C a schematic representation of a glazing arrangement according to the invention with a cross-sectional representation along the section line A-A′ through the glazing of FIG. 3A,

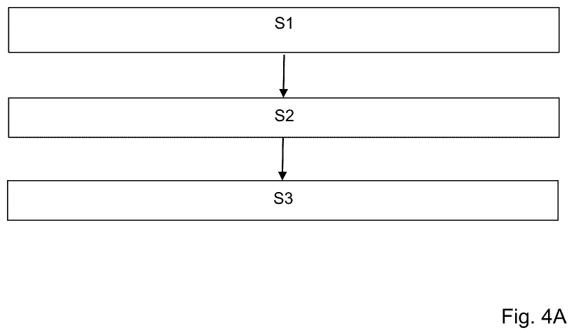

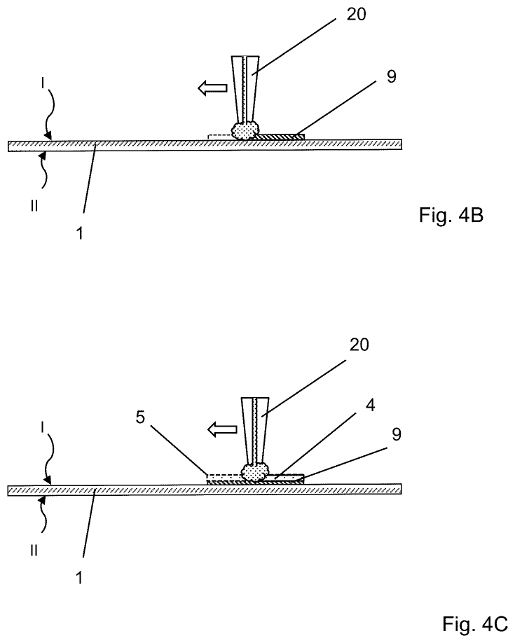

FIG. 4A a flow chart of an embodiment of the method according to the invention,

FIG. 4B a detailed view during the step S2 during production of a glazing 10 according to the invention in accordance with the example according to the invention of FIG. 3A-C, and

FIG. 4C a detailed view during the step S3 during production of a glazing 10 according to the invention in accordance with the example according to the invention of FIG. 3A-C.

FIG. 1A (FIG. 1A) depicts a plan view of an exemplary embodiment of a glazing 10 according to the invention with a coated region (communication window) 5 according to the invention. FIG. 1B depicts a schematic cross-sectional representation of the layer structure of the glazing 10, and FIG. 1C depicts a schematic representation of a glazing arrangement 100 according to the invention with a cross-sectional representation along the section line A-A′ through the glazing 10 of FIG. 1A.

The glazing 10 comprises a first pane 1 and a second pane 2 that are joined to one another via a thermoplastic intermediate layer 3. The glazing 10 is, for example, a vehicle pane and in particular the windshield of a passenger car. The first pane 1 is intended, for example, to face the exterior of the vehicle in the installed position; the second pane 2 is intended, for example, to face the interior in the installed position. The first pane 1 and the second pane 2 are made, for example, of soda lime glass. The thickness of the first pane 1 is, for example, 2.1 mm, and the thickness of the second pane 2 is 1.6 mm. The thermoplastic intermediate layer 3 is made of polyvinyl butyral (PVB) and has a thickness of 0.76 mm.

FIG. 1A depicts a plan view of the exterior-side surface I of the first pane 1. Situated behind the glazing 10 in the plan view is a camera system whose beam path of the reception region is directed onto and through the glazing 10—more precisely onto the interior-side surface IV of the second pane 2. The passage region of the beam path is provided with the reference character 7 and is also referred to as the camera window.

A coating 4 made of a layer of diamond-like carbon (DLC) is arranged on the exterior-side (first) surface I of the first pane 1 in a region 5 which is also referred to as the communication window. This DLC coating 4 is more scratch-resistant than the exterior-side surface I of the first pane 1 in the surrounding region of the coating 4.

FIG. 1B depicts a schematic cross-sectional representation of the layer structure of the glazing 10 of FIG. 1A in the region of the coating 4. The thickness d of the coating 4 here is, for example, 5 nm.

It goes without saying that the glazing 10 can have further layers or features typical for windshields. For example, further functional layers, such as IR-reflecting or IR-absorbing layers, or so-called low-E layers can be arranged on the surfaces II, III, and IV. Also, heatable layers, prints, or wires can be arranged in or on the glazing 10. Also, further functional elements such as antennas or electrically controllable optical functional elements such as illumination elements or shading elements (PDLC, SPD, an electrochromic, guest-host systems, etc.) can be arranged in or on the glazing 10.

In this example, the glazing 10 has, in particular, an opaque black print (not shown here) on the interior-side surface II of the first pane 1, which extends in strips at the upper, lower, and side edges of the pane, i.e., is implemented in the shape of a frame.

FIG. 1C depicts an exemplary embodiment of a glazing arrangement 100 according to the invention with a glazing 10. Also, a camera system 6 is arranged on the interior-side surface IV of the second pane 2, which can, for example, be used for a vision based driving assistance system.

The beam path 8 of the camera system 6 is directed completely through the region 5 coated with the coating 4. In particular, the beam path 8 of the camera system 6 runs in its entire passage region 7 through the exterior-side surface I of the first pane 1 (also called the camera window) within the region 5 formed by the coating 4.

The center beam of the beam path 8 of the camera system 6 is oriented approx. horizontally here. The angle α between the orthonormal to the glazing 10 (shown here as the orthonormal to the interior-side surface IV of the second pane 2) and the center of the beam path 8 of the camera system 6 is 73° here, for example.

Windshields of passenger cars are typically installed flat, with an insulation angle α relative to the vertical of 72° here, for example. It goes without saying that in applications in other vehicle types, such as buses or tractors, the installation angle can be even smaller, for example, 15°.

The communication window 5 is suitable for ensuring through-vision for a camera system 6 or other optical sensors. For that purpose, the camera window, i.e., the passage region 7 of the optical beam path 8 of the camera system 6 through the glazing 10, is arranged completely within the region 5 of the communication window provided with the coating 4. The coating 4 in the communication window 5 is hardly perceivable optically for the camera system 6 and does not interfere with through-vision through the glazing 10. On the contrary, as a result of its scratch resistance, the surface of the coating 4 is particularly smooth and has only a few scratches and defects that interfere with the optical signal. This is particularly important for use in vehicles and camera systems 6 with high optical requirements, as is the case with vision-based driver assistance systems (FAS) or advanced driver assistance systems (ADAS).

FIG. 2A depicts a flow chart of an embodiment of the method according to the invention for producing the glazing 10 according to the invention of FIG. 1A-C.

For this purpose, in a first step S1, at least a first pane 1 and a second pane 2 are cut out of larger planar glass panes, bent at temperatures of approx. 640° C., and then laminated to one another via a thermoplastic intermediate layer 3, for example, in an autoclave process at temperatures of approx. 120° C., to form a composite pane.

Subsequently, in a second step S2, for example, the coating 4 made of diamond-like carbon is deposited via a process for atmospheric pressure plasma-enhanced chemical vapor deposition (AP-PECVD) in a local region 5 of a communication window.

FIG. 2B schematically depicts the deposition process in which the coating 4 is deposited out of a plasma nozzle 20 on the exterior-side surface I of the first pane 1. In this process, the plasma nozzle 20 and/or the glazing can be moved over the exterior-side surface I of the first pane 1 by a robot, an XY displacement table, an XYZ displacement table, or another traversing device, and a coating 4 made of diamond-like carbon according to the invention can be deposited locally below the nozzle outlet.

FIG. 3A depicts a plan view of an exemplary embodiment of another glazing 10 according to the invention with a communication window 5. FIG. 3B depicts a schematic cross-sectional representation of the layer structure of the glazing 10 and FIG. 3C depicts a schematic representation of another glazing arrangement 100 according to the invention with a cross-sectional representation along the section line A-A′ through the glazing 10 of FIG. 3A.

FIG. 4A depicts a flow chart of another embodiment of the method according to the invention for producing the glazing 10 according to the invention of FIG. 3A-C. FIG. 4B and FIG. 4C depict detailed representations of selected steps.

The glazing 10 and the glazing arrangement 100 of FIG. 3A-C essentially correspond to the glazing 10 and the glazing arrangement 100 of FIG. 1A-C such that only the differences are dealt with here and, for the rest, reference is made to the description for FIG. 1A-C. The same applies to the description of the production process for FIG. 4A-C, which essentially corresponds to the production process in accordance with FIGS. 2A and 2B.

The glazing 10 of FIG. 3A relates to a single glass pane, for example, a rear window of a passenger car made of single-pane safety glass. Since the glazing 10 comprises only a single glass pane, the so-called “first” pane 1 here is the single pane of the glazing 10. The exterior-side surface I of the glazing 10 is intended, for example, to face the exterior of the vehicle in the installed position. The (first) pane 1 is made, for example, of thermally toughened soda lime glass. The thickness of the (first) pane 1 is, for example, 2.1 mm.

FIG. 3A depicts a plan view of the exterior-side surface I of the (first) pane 1. Situated behind the glazing 10 in the plan view is a camera system, whose beam path of the reception region is directed onto and through the glazing 10—more precisely onto the interior-side surface II of the (first) pane I.

The coating 4 made of a layer of diamond-like carbon is arranged on the exterior-side (first) surface I of the first pane 1 in a region 5 (i.e., the communication window). The coating 4 is more scratch-resistant than the exterior-side surface I of the first pane 1 in the surrounding region of the coating 4.

FIG. 3B depicts a schematic cross-sectional representation of the layer structure of the glazing 10 of FIG. 3A in the region of the coating 4. The thickness d of the coating 4 here is, for example, 5 nm.

It goes without saying that the glazing 10 can have further layers or features typical for rear windows. For example, further functional layers, such as IR-reflecting or IR-absorbing layers or so-called low-E layers can be arranged on the interior-side surface II. Also, antenna conductors and/or heatable layers, prints, or wires can be arranged in or on the glazing 10.

In this example, the glazing 10 has, in particular, an opaque black print (not shown here) on the interior-side surface II of the first pane 1, which extends in strips at the upper and lower edges of the pane. It goes without saying that the black print can also be implemented in the shape of a frame.

FIG. 3C depicts an exemplary embodiment of a glazing arrangement 100 according to the invention with a glazing 10. Also, a camera system 6 is arranged on the interior-side surface II of the glazing 10, which can be used, for example, for a vision-based driving assistance system or as a rear view camera.

The beam path 8 of the camera system 6 is directed substantially completely through the region 5 coated with the coating 4. In particular, the beam path 8 of the camera system 6 runs in its entire passage region 7 through the exterior-side surface I of the first pane 1 within the region 5 (communication window) formed by the coating 4. In the example depicted, the region 5 and the passage region 7 are (for example) congruent. In contrast to the exemplary embodiment of FIG. 1A-C, an adhesion layer 9 made, for example, of silicon oxide, is arranged between the exterior-side surface I of the first pane 1 and the coating 4.

The center beam of the beam path 8 of the camera system 6 is oriented approx. horizontally here.

The communication window 5 is suitable for ensuring the through-vision for the camera system 6 or other optical sensors. For that purpose, the camera window, i.e., the passage region 7 of the optical beam path 8 of the camera system 6 through the glazing 10, is arranged congruently with the region 5 of the communication window provided with the coating 4. The coating 4 in the communication window 5 is hardly perceivable optically for the camera system 6 and does not interfere with through-vision through the glazing 10. On the contrary, as a result of its scratch resistance, the surface of the coating 4 is particularly smooth and has only a few scratches and defects that interfere with the optical signal. This is particularly important for use in vehicles and camera systems 6 with high optical requirements, as is the case with vision-based driver assistance systems (FAS) or advanced driver assistance systems (ADAS).

FIG. 4A depicts a flow chart of an embodiment of the method according to the invention for producing the glazing 10 according to the invention of FIG. 3A-C.

For this purpose, in a first step S1, at least the (first) pane 1 is cut out of a larger planar glass pane, bent at temperatures of, for example, approx. 690° C. and then quenched, for example, by a cold air flow (thermal toughening). A thermally toughened single pane of single pane safety glass is thus created.

Subsequently, in a second step S2, an adhesion-enhancing layer 9 (also referred to, in short, in the following as adhesion layer 9) is deposited in a local region of the communication window 5 by a process for atmospheric pressure plasma-enhanced CVD deposition. The adhesion layer 9 is, for example, silicon oxide-based and is made here, for example, of silicon oxide.

FIG. 4B schematically depicts the deposition process in which the adhesion layer 9 is deposited out of a plasma nozzle 20 on the exterior-side surface I of the (first) pane 1. In this process, the plasma nozzle 20 and/or the glazing 10 can be moved over the exterior-side surface I of the first pane 1 by a robot, an XY displacement table, an XYZ displacement table, or another traversing device; and a layer of, for example, silicon oxide can be deposited locally below the nozzle outlet.

Subsequently, in a third step S3, the coating 4 made of diamond-like carbon is deposited in the local region of the communication window 5 and onto the adhesion layer 9 by a process for atmospheric pressure plasma-enhanced CVD deposition.

FIG. 4C schematically depicts the deposition process in which the coating 4 of the adhesion layer 9 is deposited out of a plasma nozzle 20. Here, again, a plasma nozzle 20 and/or the glazing 10 can be moved over the adhesion layer 9 on the exterior-side surface I of the first pane 1 by a robot, an XY displacement table, an XYZ displacement table, or another traversing device; and a coating 4 made of diamond-like carbon can be deposited locally below the nozzle outlet.

It goes without saying that after the application of the coating 4, the glazing 10 is no longer exposed to high temperatures, as these occur, for example, during glass bending. Consequently, there is no longer any risk of damage for the diamond-like carbon layer of the coating 4.

The following Table 1 shows production parameters and measurement results from investigations of four Samples 1-4 coated with a DLC coating in an AP-PECVD process.

TABLE 1

| | Sample 1 | Sample 2 | Sample 3 | Sample 4 |
|---|---|---|---|---|
| Distance between the | 15 | 15 | 15 | 15 |
| plasma nozzle and the | | | | |
| glass pane | | | | |
| in mm | | | | |
| Displacement in | 30 | 30 | 30 | 30 |
| m/min. | | | | |
| Flow of coating | 200 | 100 | 50 | 25 |
| precursor compound | | | | |
| in l/h | | | | |
| T_{L} (D65/2°) | 83.1 | 86.8 | 89.6 | 90.2 |
| Thickness of the | Approx. | Approx. | Approx. | Approx. |
| DLC coating | 40 nm | 24 nm | 7 nm | 4 nm |
| in nm | | | | |
| Scratch resistance in | moderate | good | very good | excellent |
| the Erichsen Scratch | | | | |
| Test | | | | |
| at 10N normal force | | | | |

The DLC coating of the Samples 1-4 was deposited with atmospheric pressure plasma-enhanced chemical gas vapor deposition (AP-PECVD) on a 2.1-mm-thick, clear float glass pane of the type SGG Planiclear (PLC) of the company Saint Gobain Glass. Acetylene (C₂H₂) was used as the coating precursor compound (precursor). The transmittance T_{L} was measured with standard illuminant D65 at an angle α of 2° in each case. Scratch resistance was measured with an Erichsen Hardness Tester Model 413 and a tip with a diameter of 1 mm at a normal force of 10 N.

As Table 1 shows, the AP-PECVD method was able to produce DCL coatings with good to excellent scratch resistance properties.

The glazings 10 according to the invention with communication windows 5 correspondingly coated are much better suited for low-interference and low-distortion through-vision and operation of high-sensitivity optical sensors and camera systems than prior art glazings and meet the requirements for modern vision-based driver assistance systems.

As a result of the deposition process according to the invention using atmospheric pressure chemical vapor deposition (AP-CVD) or atmospheric pressure plasma-enhanced chemical vapor deposition (AP-PECVD), DLC coating can be carried out after bending and annealing of the glazing. I.e., after DLC coating, the glazing no longer has to be heated to temperatures critical for the DLC coating. Expensive techniques necessary to avoid oxidation that use protection layers and release layers that prevent DLC coatings from burning off during temperature treatment for bending or annealing are eliminated.

The method according to the invention allows targeted, fast, local, and, consequently, economical deposition of the DLC coating.

### LIST OF REFERENCE CHARACTERS

1 first pane
2 second pane
3 thermoplastic intermediate layer
4 coating made of diamond-like carbon
5 region of the coating 4, communication window
6 camera system
7 passage region of the beam path 8, camera window
8 beam path
9 adhesion layer
10 glazing
20 plasma nozzle
100 glazing arrangement
I first/exterior-side surface of the first pane 1
II second/interior-side surface of the first pane 1
III first/exterior-side surface of the second pane 2
IV second/interior-side surface of the second pane 2
d thickness of the coating 4
F1 area of the exterior-side surface I of the first pane 1
F4 area of the coating 4
DLC diamond-like carbon
AP-CVD atmospheric pressure chemical vapor deposition
AP-PECVD atmospheric pressure plasma-enhanced chemical vapor deposition
S1, S2, S3 step
T_{L} transmittance
A-A′ section line

1. A glazing comprising:
a first pane with an exterior-side surface and an interior-side surface,
wherein
the first pane contains or consists of soda lime glass, and
a coating made of diamond-like carbon is arranged on the exterior-side surface.

2. The glazing according to claim 1, wherein the coating is arranged on the exterior-side surface of the first pane with an atmospheric pressure chemical vapor deposition method.

3. The glazing according to claim 1, wherein the first pane is monolithic.

4. The glazing according to claim 1, wherein the coating is arranged in some sections on the exterior-side surface.

5. The glazing according to claim 1, wherein an area of the coating is from 0.1% to 95% of an area of the exterior-side surface of the first pane.

6. The glazing according to claim 1, wherein the diamond-like carbon of the coating includes or consists of a mixture of sp³- and sp²-hybridized carbon with a proportion of at least 20% of sp³-hybridized carbon.

7. The glazing according to claim 1, wherein the coating is doped.

8. The glazing according to claim 1, wherein the coating has a thickness d of 1 nm to 20 nm.

9. The glazing according to claim 1, wherein the coating has higher scratch resistance than the exterior-side surface of the first pane.

10. The glazing according to claim 1, wherein the interior-side surface of the first pane is joined flat to an exterior-side surface of a second pane via at least one thermoplastic intermediate layer.

11. A glazing arrangement, comprising:
a) a glazing according to claim 1 and
b) at least one optical sensor or at least one camera system, whose beam path is directed through the region of the coating.

12. The glazing arrangement according to claim 11, wherein the region of the coating completely contains a passage region of the beam path.

13. A method for producing a glazing according to claim 1, comprising the following steps in the order indicated:
a) annealing or bending at least one first pane,
b) depositing a coating made of diamond-like carbon on the exterior-side surface of the first pane with an atmospheric pressure chemical vapor deposition method.

14. The method according to claim 13, wherein prior to step b) an adhesion layer is deposited on the exterior-side surface of the first pane, and the coating is deposited in step b) on the adhesion layer.

15. The method according to claim 13, wherein the coating is deposited out of a plasma nozzle on a subregion of the exterior-side surface of the first pane.

16. The method according to claim 13, wherein, after step b), all following steps for producing the glazing (10) are carried out at a temperature of less than 400° C.

17. A method comprising providing the glazing according to claim 1 in a vehicle of locomotion for travel on land, in the air, or on water, or as built-in part in furniture, appliance, and building, having optical sensors and camera systems, whose beam path passes through the region of the coating.

18. The glazing according to claim 1, wherein the glazing is a vehicle glazing.

19. The glazing according to claim 2, wherein the atmospheric pressure chemical vapor deposition method is an atmospheric pressure plasma-enhanced chemical vapor deposition method.

20. The glazing according to claim 3, wherein the first pane has a continuous and uniform exterior-side surface.
